(19) United States
(12) Patent Application Publication
(10) Pub. No.: US 2026/0359648 A1
(43) Pub. Date: Nov. 12, 2026

(54) SELF-SUPERVISED AND REPRESENTATION LEARNING-BASED THIN FILM THICKNESS PREDICTION METHOD AND SYSTEM

(71) Applicant: Zhejiang University, Hangzhou (CN)

(72) Inventors: Yining Chen, Hangzhou (CN); Weiping Xie, Hangzhou (CN); Dawei Gao, Hangzhou (CN); Dingwei Chen, Hangzhou (CN)

(21) Appl. No.: 19/399,693

(22) Filed: Nov. 25, 2025

(30) Foreign Application Priority Data
May 9, 2025 (CN) 202510593095.0

(51) Int. Cl. G06N 3/0895; G06N 3/096

(52) U.S. Cl. CPC G06N 3/0895; G06N 3/096

(57) ABSTRACT

Systems and methods predict thin-film thickness in semiconductor manufacturing using self-supervised representation learning. An encoder is pre-trained on an unlabeled second training set and fine-tuned on a labeled first training set while jointly training a dynamic feature selector and a regression head. The selector performs adaptive dimensionality reduction on labeled data, and the fine-tuned encoder initializes a global prototype projection space. Embedded representations of the reduced data are generated by the encoder, a feature representation head computes projection coordinates, and a composite loss—including projection, regression, diversity, and global-prototype orthogonality terms—updates model parameters. During inference, process data are passed through the selector, encoder, and regressor to output thickness values. The approach reduces reliance on labeled data, automates feature selection for complex, high-dimensional semiconductor data, mitigates representation aliasing and localization, and yields accurate, stable predictions.

### TECHNICAL FIELD

The present invention belongs to the technical field of machine learning and artificial intelligence, and particularly relates to a self-supervised and representation learning-based thin film thickness prediction method and system.

### BACKGROUND

In the field of semiconductor manufacturing, precise control of the production process is crucial for ensuring high-quality products and operational efficiency. Chemical Vapor Deposition (CVD) is one of the key processes for thin film preparation, and its process quality directly affects the reliability of semiconductor devices. However, given the diversity and complexity of process variables and potential performance drift of the equipment itself, the uniformity of thin film thickness remains a highly challenging issue. Traditional Virtual Metrology (VM) technologies mainly rely on physics-based models or machine learning prediction methods. Existing deep learning prediction methods suffer from the following three problems:
(1) Dependence on large amounts of labeled data: The accuracy of current deep learning methods for thin film thickness prediction highly depends on large amounts of labeled data. However, due to the time-consuming and costly measurement process, obtaining labeled data is extremely difficult.
(2) Feature selection problem: Feature selection methods are mainly divided into three categories: filter methods, wrapper methods, and embedded methods. Filter methods are computationally simple but do not consider interactions between features, making them difficult to apply to highly complex semiconductor manufacturing data. Wrapper methods select features by iteratively training models multiple times, which is computationally expensive, suitable for traditional machine learning methods, but not ideal for deep learning. Existing deep learning feature screening methods lack in-depth research on embedded methods, i.e., the absence of dynamic feature screening mechanisms, leading many deep learning models to use raw sensor data directly for prediction without effectively screening key features. This may cause redundant information to interfere with prediction results and reduce the model's generalization ability.
(3) Representation aliasing and localization problem: Feature representations learned by existing deep learning methods often suffer from aliasing phenomena, lacking clear separability, thereby affecting decision clarity and accuracy. Furthermore, the feature representation of each sample is usually independent, ignoring the correlation of the global data structure, leading to unstable prediction results.

### SUMMARY

In response to the above problems, the present invention proposes a self-supervised and representation learning-based thin film thickness prediction method and system. It utilizes unlabeled data to pre-train an encoder, reducing dependence on labeled data and enhancing data features to improve model generalization ability. It also improves prediction accuracy by constructing a dynamic selector through embedded feature selection. Furthermore, it optimizes the representation space by constructing a global prototype projection space, reducing representation aliasing and localization problems to make prediction results more stable. By leveraging the optimal transport mechanism and orthogonality constraints, it enhances prediction reliability and the model's adaptability to different data distributions, respectively.

The technical solution adopted by the present invention is as follows:

In a first aspect, the present invention proposes a self-supervised and representation learning-based thin film thickness prediction method, comprising the following steps:
(1) Collecting raw wafer manufacturing process data and thin film thickness measurement data, preprocessing successfully matched pairs of raw process data and measurement data to form a first training set, and preprocessing unmatched raw process data to form a second training set;
(2) Pre-training an encoder using the second training set, then fine-tuning the encoder using the first training set while simultaneously training a dynamic feature selector and a regression head;
(3) Using the dynamic feature selector to reduce the dimensionality of the process data in the first training set, and using the fine-tuned encoder on the dimensionality-reduced process data to initialize a global prototype projection space;
(4) Using the most recently updated encoder to generate embedded representations of the dimensionality-reduced process data, calculating the projection coordinates of the embedded representations in the global prototype projection space through a feature representation head, calculating a projection loss based on the projection distribution, calculating a regression loss based on the regression head, simultaneously introducing a diversity loss and a global prototype orthogonality loss, and jointly using the total loss to iteratively update the encoder, regression head, feature representation head, and synchronously update the global prototype projection space;
(5) Using actual wafer manufacturing process data as input, and predicting the thin film thickness utilizing the dynamic feature selector, encoder, and regression head.

Further, said preprocessing refers to preliminary screening of features in the process data, wherein the screened features include deposition time, buffer pressure, wafer processing temperature, lateral and top silane gas reaction times, and top, bias, and lateral radio frequency (RF) reflected power.

Further, when pre-training the encoder using the second training set, the K-Means clustering method is used to generate pseudo measurement data for the second training set as pseudo-labels for training, while simultaneously perturbing the process data in the second training set;

Further, said fine-tuning the encoder using the first training set while simultaneously training a dynamic feature selector and a regression head comprises: Using the dynamic feature selector to screen features of the process data in the first training set, obtaining dimensionality-reduced process data;

Using the pre-trained feature encoder to generate embedded representations of the dimensionality-reduced process data;

Using the regression head to predict the thin film thickness based on the embedded representations;

Calculating a loss based on the predicted film thickness and the actual measurement data, and updating the parameters of the encoder, dynamic feature selector, and regression head.

Further, said dynamic feature selector is specifically:

Introducing a random gating variable z∈[0,1]^{d}, where the gating value zⱼ is defined as:

zⱼ=max(0,min(1,μⱼ+ϵⱼ));

where, μⱼ is the j-th trainable parameter in the dynamic feature selector, j=1,2, . . . d; d represents the number of features of a sample in the training set; ϵⱼ is an independent sampling parameter for the j-th trainable parameter, which follows a Gaussian distribution; feature screening is achieved by calculating the Hadamard product of the process data and the random gating variable z, and a regularization term is introduced during the training process of the dynamic feature selector.

Further, the initialization process of the global prototype projection space is:

Using the fine-tuned encoder to generate embedded representations of the dimensionality-reduced process data;

Clustering the embedded representations, considering each cluster center as a prototype, obtaining a global prototype projection space containing several prototypes.

Further, said calculating the projection coordinates of the embedded representation in the global prototype projection space through the feature representation head is expressed as:

rᵢ=fᵣ(Eᵢ);

The projection coordinate rᵢ of the embedded representation Eᵢ and the global prototype projection space satisfy the following relationship:

$${E}_{i} = {\sum }_{k = 1}^{{K}_{r}} {( {r}_{i} )}^{k} {β}_{k} ;$$

where, Kᵣ represents the number of prototypes in the global prototype projection space, βₖ represents the k-th prototype in the global prototype projection space, fᵣ(.) represents the feature representation head.

Further, said diversity loss calculation process is:

Dividing the range of measurement data in the first training set into several sub-intervals, considering process data within the same sub-interval as a positive sample pair, considering process data from different sub-intervals as a negative sample pair, and calculating a contrastive learning loss for the projection coordinates based on the positive and negative samples.

Further, said projection loss refers to the optimal transport distance loss between the distribution of projection coordinates and the distribution of embedded representations, and said global prototype orthogonality loss refers to the orthogonality constraint satisfied by the global prototype projection space.

In a second aspect, the present invention proposes a self-supervised and representation learning-based thin film thickness prediction system, used to implement the aforementioned self-supervised and representation learning-based thin film thickness prediction method.

The beneficial effects of the present invention are:

The present invention first pre-trains the encoder using unlabeled wafer manufacturing process data, which not only reduces dependence on large amounts of labeled data but also enhances data features, thereby improving model generalization ability; it employs an embedded feature selection method to construct a dynamic feature selector, enabling the model to automatically screen the most representative wafer manufacturing process features, reduce interference from redundant information, and effectively improve prediction accuracy; in terms of representation space optimization, by constructing a global prototype projection space, it improves the separability of embedded representations of wafer manufacturing process data, reduces representation aliasing problems, making thin film thickness prediction results more stable; it utilizes the optimal transport mechanism to achieve optimal transport loss optimization, prompting the model to learn the global structural information of the data more effectively and enhancing prediction reliability; it uses orthogonality constraints to improve robustness, making global prototypes more independent and enhancing the model's adaptability to different data distributions.

### BRIEF DESCRIPTION OF THE DRAWINGS

FIG. 1 is a flowchart of the self-supervised and representation learning-based thin film thickness prediction method;

FIG. 2 is a framework diagram of the self-supervised and representation learning-based thin film thickness prediction method;

FIG. 3 is a schematic diagram of the self-supervised pre-training phase;

FIG. 4 is a schematic diagram of the fine-tuning training phase;

FIG. 5 is a schematic diagram of the representation learning phase.

### DESCRIPTION OF EMBODIMENTS

The following description is provided to disclose the present invention to enable those skilled in the art to implement it.

The drawings are only schematic illustrations of the present invention and are not necessarily drawn to scale. Some block diagrams shown in the drawings are functional entities and do not necessarily correspond to physically or logically independent entities. These functional entities may be implemented in software form, or implemented in one or more hardware modules or integrated circuits, or implemented in different networks and/or processor devices and/or microcontroller devices.

The flowcharts shown in the drawings are only exemplary illustrations and do not necessarily include all steps. For example, some steps may be decomposed, while others may be merged or partially merged, so the actual execution order may change according to the actual situation.

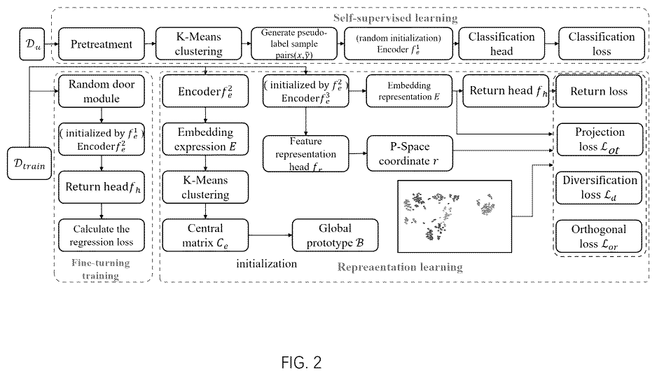

The self-supervised and representation learning-based thin film thickness prediction method proposed by the present invention is named SGT_SRL (Self-Supervised and Representation-Aware Transformer). The overall framework structure is shown in FIG. 2, combining self-supervised pre-training, fine-tuning training phase, and representation learning phase. It can effectively utilize CVD process data to predict thin film thickness. The training processes of the three phases are detailed below.

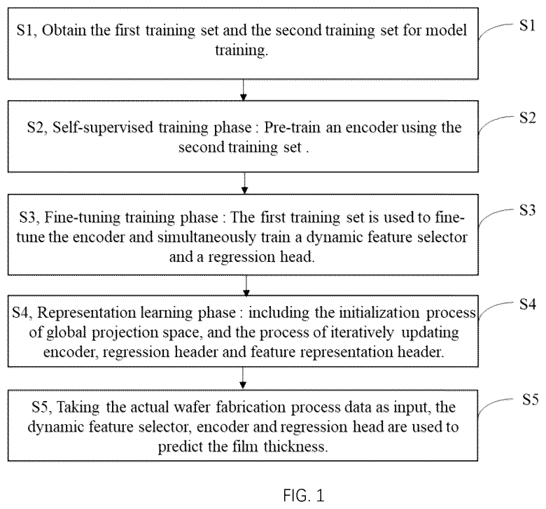

As shown in FIG. 1, the implementation process of the present invention mainly includes the following steps:

Step S1, Obtain the first training set and the second training set for model training.

Collect real-time data from the Fault Detection and Classification (FDC) system during wafer manufacturing, including process data and measurement data from key semiconductor manufacturing steps. Regard the process data as process variables and the measurement data as target variables.

In specific implementation, parameters such as lateral/top silane (SiH₄) gas flow, top/bias/lateral RF reflected power, deposition time, and front-line pressure from the CVD process were collected as process data, and the final thin film thickness was used as measurement data.

Successfully matched pairs of raw process data and measurement data are preprocessed to form the first training set. Unmatched raw process data is preprocessed to form the second training set. These two datasets are used for the subsequent SGT_SRL training. The SGT_SRL training process includes 3 phases: the self-supervised pre-training phase, the fine-tuning training phase, and the representation learning phase. The model of the present invention is defined as F_{θ,μ}:X→Y, with parameters θ and μ, where F_{θ,μ} consists of a dynamic feature selector fₛ, an encoder fₑ, and a regression head fₕ.

Step S2, Self-supervised pre-training phase: Pre-train an encoder fₑ using the second training set.

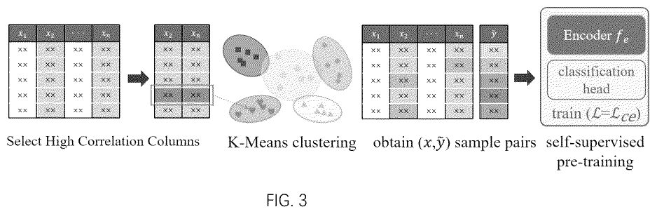

As shown in FIG. 3, this phase requires creating a pre-training task from the unlabeled second training set. In practice, there is a high correlation between certain input process data features and the original measurement data. For example, the original task uses features TOP_MEAN_1, SID_MEAN_2, and SID_MEAN_3 to predict film thickness BTH. Deposition time TIME_1 has a high correlation with film thickness BTH, so features TOP_MEAN_1, SID_MEAN_2, and SID_MEAN_3 can be used to predict deposition time TIME_1 to create a pre-training task. To improve the diversity and reasonableness of pseudo-labels, this embodiment first selects the top 10 features with the highest correlation for clustering to generate pseudo-labels.

First, define a binary mask matrix:

m=[m₁, . . . ,m_{d}]^{T}∈{0,1}^{d}

where d is the feature dimension of the input data, which is 81, Σᵢ mᵢ=10, mᵢ=1 indicates the feature is selected, mᵢ=0 indicates the feature is not selected. The features selected by the mask form a new input:

sq(x⊙m)∈

[symbol]

where ⊙ represents element-wise multiplication, sq(⋅) represents removing elements where the mask value is 0. Based on the selected features, run K-Means clustering to generate task labels:

$${min}_{C ∈ {R}^{w \times K} s} \frac{1}{{N}_{u}} {\sum }_{i = 1}^{{N}_{u}} {min}_{{\tilde{y}}_{u , i} ∈ {\{ 0 , 1 \}}^{{K}_{s}}} {‖ sq ( {x}_{u , i} m ) - C {\tilde{y}}_{u , i} ‖}_{2}^{2}$$

where, x_{u,i} represents the i-th unmatched raw process data, m represents the binary mask matrix used for preprocessing the raw process data, sq(.) represents the features of the preprocessed process data, with feature dimension w; C represents the cluster center matrix, \tilde{y}_{u,i} represents the pseudo-label of the i-th process data in the second training set, which is a one-hot encoding of dimension Kₛ, and

$${\tilde{y}}_{u , i}^{T} {1}_{{K}_{s}} = 1 ,$$

1_{K}_{ₛ} is an all-ones vector, Nᵤ represents the number of samples in the second training set,

$${‖ \cdot ‖}_{2}^{2}$$

represents the square of the L2 norm. K_{S} is the number of cluster centers, set to 100.

To prevent the model from simply memorizing the data, introduce a random variable:

p=[p₁, . . . , p_{d}]^{T}∈{0,1}^{d}, pᵢ~Bernoulli(0.5)

where pᵢ follows a Bernoulli distribution with parameter 0.5; parameter 0.5 is the probability that the random variable takes the value 1; the superscript T represents transpose.

For positions where p⊙sq(x_{u,i}⊙m) is 1, replace them with the mean of that feature column, thereby obtaining the perturbed input [symbol] . Finally, the pre-training task dataset is constructed and fed into the model for pre-training:

$${\tilde{D}}_{u} = {\{ {\tilde{x}}_{u , i} , {\tilde{y}}_{u , i} \}}_{i = 1}^{{N}_{u}}$$

The process of pre-training the model is: use the perturbed process data \tilde{x}_{u,i} as input to the encoder, predict the pseudo-label of this process data through a classification head, and update the encoder and classification head based on the prediction result and the actual pseudo-label. Here, [the encoder can adopt a Transformer architecture,]{.mark} and the classification head can be implemented using one or more linear layers. The classification head is only used during the training of this phase.

Step S3, Fine-tuning training phase: Fine-tune the encoder using the first training set and simultaneously train a dynamic feature selector and a regression head.

This phase uses the first training set for training.

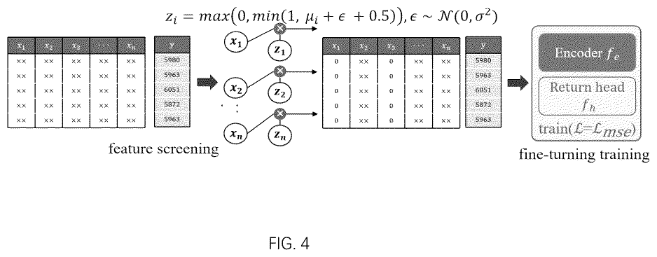

As shown in FIG. 4, the encoder fₑ is now initialized with the parameters from the pre-trained encoder of the previous stage. To perform feature selection, an embedded method is adopted. Specifically, a random gating variable z∈[0,1]^{d} is introduced to achieve feature screening. For each feature k=1, . . . , d, sample independently:

ϵⱼ~ [symbol] (0,σ²)

where σ is a fixed noise intensity. The gating value zⱼ is defined as follows:

zⱼ=max(0,min(1,μⱼ+ϵⱼ))

where μ=[μ₁, . . . , μ_{d}]^{T} ∈R^{d} are the trainable parameters of the feature selector fₛ. When zⱼ→1, the feature is fully retained; when zⱼ→0, the feature is completely suppressed. The input process data, after feature screening, is passed to the encoder and regression head to calculate the regression loss:

$${ℒ}_{task} = \frac{1}{N} {\sum }_{j = 1}^{N} {ℒ}_{mse} ( {f}_{h} ( {f}_{e} ( {x}_{j} ⊙ z ) ) , {y}_{j} )$$

To enhance feature sparsity, a regularization term is introduced:

$$ℛ = λ {\sum }_{j = 1}^{d} Φ ( \frac{{µ}_{j}}{σ} )$$

where Φ(⋅) is the cumulative distribution function (CDF) of the standard normal distribution, and λ is used to adjust the weight of the regularization term in the total loss. This regularization term encourages μj→0 for non-important features, thereby closing the corresponding gate. Based on the result of the loss function, update the model parameters μ and θ:

θ:=θ−γ_{θ}∇_{θ} [symbol] ₜₐₛₖ, μ:μ−γ_{μ}∇_{μ}( [symbol] ₜₐₛₖ+ [symbol] )

γ_{θ} and γ_{μ} are the learning rates for the encoder fₑ and regression head fₕ parameters θ and the feature selector fₛ parameters μ, respectively. Repeat the above steps iteratively to complete the fine-tuning step.

Step S4, Representation learning phase.

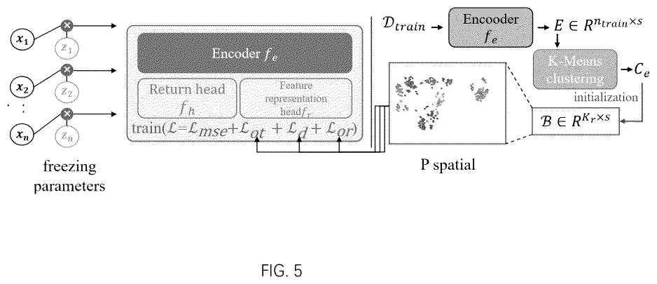

As shown in FIG. 5, this phase includes the process of initializing the global prototype projection space and iteratively updating the encoder, regression head, feature representation head, and the projection space.

First, this phase optimizes the data representation by constructing a Prototype-Based Projection Space (P-Space), improving the model's generalization ability and reducing aliasing issues between different data features. The training data is processed through fₛ and fₑ fine-tuned in step S3 to obtain embedded representations E∈Rⁿ^{ₜᵣₐᵢₙ}^{×s}, where nₜᵣₐᵢₙ represents the number of samples in a batch of training data (from the first training set). Perform K-Means clustering on E to obtain the cluster center matrix Cₑ, and use it to initialize the global prototypes:

$$ℬ = {\{ {β}_{k} \}}_{k = 1}^{{K}_{r}} ∈ {R}^{{K}_{r} \times s}$$

where Kᵣ is the number of clusters, the cluster center matrix for each cluster represents a vector of length s, recorded as a prototype; βₖ represents the k-th prototype. Define the prototype projection space as the projection space with the global prototypes [symbol] as basis vectors, where the embedded representation Eᵢ of each sample is formalized as

$${\sum }_{k = 1}^{{K}_{r}} {( {r}_{i} )}^{k} {β}_{k} , {r}_{i} = {\{ {r}_{i}^{k} \}}_{k = 1}^{{K}_{r}} ∈ {R}^{{K}_{r} \times 1} .$$

In this embodiment, the embedded representation Eᵢ of the i-th sample calculates its projection coordinate rᵢ=fᵣ(Eᵢ) in the prototype projection space through the feature representation head fᵣ. The feature representation head fᵣ can be implemented using one or more linear layers.

The projection distributions of the embedded representation and the projection coordinate are represented as:

$${Q}_{i} = {\sum }_{k = 1}^{{K}_{r}} {( {r}_{i} )}^{k} {δ}_{{β}_{k}}$$

$${P}_{i} = {δ}_{{e}_{i}}$$

where δ_{β}_{ₖ} represents the Dirac function at δ_{E}_{ᵢ}, Qᵢ represents the Dirac function at Eᵢ, Qᵢ and Pᵢ are the projection distributions of the embedded representation and the projection coordinate, respectively.

To make the prototypes βₖ capture global data structure information, the optimal transport (OT) distance is used to calculate the projection loss:

$${ℒ}_{ot} = \frac{1}{N} {\sum }_{i = 1}^{N} OT ( {P}_{i} , {Q}_{i} )$$

where N is the number of samples.

Considering that direct optimization might lead to coordinate collapse, a constraint is introduced to distribute the projection coordinates to different regions. This embodiment divides the range of the measurement data into t sub-intervals, where t=1+log(n_{b}), n_{b} is the batch size. Samples within the same partition are considered positive pairs, and samples across partitions are negative pairs. The optimization objective is:

$${ℒ}_{d} = - {\sum }_{i = 1}^{{n}_{b}} {\sum }_{j = 1}^{{n}_{b}} 1 \{ {y}_{i} , {y}_{j} ∈ Positive\_sample \_pair \} log \frac{exp ( cos ( {r}_{i} , {r}_{j} ) )}{{\sum }_{i = 1}^{{n}_{b}} {\sum }_{j = 1}^{{n}_{b}} exp ( cos ( {r}_{i} , {r}_{j} ) )}$$

where 1{yᵢ,yⱼ∈Positive_sample_pair} is the indicator function, which is 1 when yᵢ,yⱼ form a positive pair.

Furthermore, the global prototype projection space is composed of global prototypes. To ensure the independence of the prototypes, an orthogonality constraint needs to be satisfied:

$${ℒ}_{or} = \frac{{‖ M ‖}_{1}}{{‖ M ‖}_{2}^{2}} + max ( 0 , \vert {K}_{r} - {‖ M ‖}_{1} \vert )$$

where

$$M = \frac{ℬ \cdot {ℬ}^{T}}{{‖ ℬ ‖}_{2} {‖ ℬ ‖}_{2}^{T}} ∈ {R}^{{K}_{r} \times {K}_{r}} .$$

The first term

$$\frac{{‖ M ‖}_{1}}{{‖ M ‖}_{2}^{2}}$$

forces M to become sparse, and the second term ensures ∥M∥₁→Kᵣ. By combining the task loss [symbol] ₜₐₛₖ with [symbol] ₒₜ, [symbol] _{d}, and [symbol] ₒᵣ, and iteratively updating the parameters θₑ, θᵣ, θₕ, [symbol] , the final model F_{θ,μ} for prediction is obtained.

It should be noted that the calculation formulas for [symbol] ₒₜ [symbol] [symbol] _{d} [symbol] [symbol] ₒᵣ, and [symbol] ₜₐₛₖ are given above, while [symbol] ₜₐₛₖ refers to the conventional regression loss, i.e., the loss between the predicted film thickness and the actual measurement data.

Step S5. Use actual wafer manufacturing process data as input, and utilize the dynamic feature selector, encoder, and regression head to predict the thin film thickness. Here, the input process data is first screened by the dynamic feature selector to obtain dimensionality-reduced process data; then the feature encoder is used to generate embedded representations of the dimensionality-reduced process data; finally, the regression head is used to predict the thin film thickness based on the embedded representations.

To quantitatively evaluate the performance of the SGT_SRL model, the following experimental validation was conducted.

Baseline and Evaluation Metric Selection: Representative methods from machine learning, deep learning, and self-supervised learning were selected for comparative evaluation. Root Mean Square Error (RMSE) and the Coefficient of Determination (R²) were used as evaluation metrics.

Deep learning methods included FT-Transformer, GNN, NODE, MDN, AutoInt, GANDALF, MLP, ResNet, TabDPT, STG, and TabTransformer. They have achieved good performance on public datasets for tabular data, leveraging self-attention mechanisms and stacking multiple network layers to achieve excellent nonlinear modeling capabilities.

TABLE 1

| | CVD-1 | | CVD-2 | |
|---|---|---|---|---|
| Methods | RMSE | R² | RMSE | R² |
| Node | 21.962 ± 0.314 | 0.685 ± 0.021 | 28.186 ± 0.900 | 0.554 ± 0.021 |
| MDN | 21.796 ± 2.376 | 0.685 ± 0.079 | 27.188 ± 1.974 | 0.584 ± 0.059 |
| AutoInt | 20.361 ± 1.166 | 0.728 ± 0.040 | 28.810 ± 1.626 | 0.533 ± 0.043 |
| GANDALF | 21.628 ± 0.606 | 0.695 ± 0.017 | 30.617 ± 1.094 | 0.473 ± 0.036 |
| Mlp | 22.405 ± 0.586 | 0.672 ± 0.016 | 30.300 ± 1.650 | 0.484 ± 0.040 |
| Resnet | 23.465 ± 0.305 | 0.641 ± 0.010 | 29.988 ± 1.184 | 0.494 ± 0.051 |
| TabDPT | 21.255 ± 1.214 | 0.704 ± 0.041 | 27.774 ± 1.230 | 0.567 ± 0.013 |
| STG | 21.929 ± 0.420 | 0.686 ± 0.016 | 29.600 ± 0.997 | 0.504 ± 0.075 |
| FastAI | 23.789 ± 0.832 | 0.629 ± 0.037 | 31.081 ± 1.475 | 0.452 ± 0.092 |
| Tabtransformer | 22.292 ± 0.773 | 0.675 ± 0.029 | 30.321 ± 0.920 | 0.483 ± 0.031 |
| LGBM | 20.970 ± 1.099 | 0.711 ± 0.041 | 24.676 ± 1.609 | 0.658 ± 0.030 |
| XGB | 21.078 ± 0.432 | 0.710 ± 0.016 | 26.265 ± 1.745 | 0.612 ± 0.040 |
| RF | 20.590 ± 0.271 | 0.723 ± 0.014 | 26.329 ± 1.291 | 0.611 ± 0.028 |
| CAT | 20.200 ± 0.505 | 0.733 ± 0.016 | 25.422 ± 1.216 | 0.637 ± 0.029 |
| ET | 20.174 ± 0.724 | 0.734 ± 0.015 | 26.121 ± 1.694 | 0.615 ± 0.051 |
| GPR | 20.141 ± 1.181 | 0.735 ± 0.027 | 27.848 ± 1.996 | 0.562 ± 0.067 |
| PLS | 20.934 ± 1.931 | 0.713 ± 0.048 | 30.289 ± 2.604 | 0.484 ± 0.067 |
| SVR | 22.012 ± 0.660 | 0.684 ± 0.013 | 29.636 ± 0.873 | 0.504 ± 0.057 |
| EN | 20.490 ± 0.604 | 0.726 ± 0.019 | 29.701 ± 1.762 | 0.504 ± 0.052 |
| LR | 23.690 ± 1.544 | 0.631 ± 0.063 | 29.359 ± 1.401 | 0.516 ± 0.031 |
| Tabnet | 24.521 ± 2.422 | 0.605 ± 0.075 | 30.568 ± 4.263 | 0.474 ± 0.115 |
| VIME | 26.366 ± 0.417 | 0.546 ± 0.015 | 31.221 ± 1.224 | 0.452 ± 0.046 |
| SGT_SRL | 18.796 ± 0.658 | 0.769 ± 0.021 | 26.908 ± 0.786 | 0.590 ± 0.058 |

Machine learning methods included LightGBM, XGBoost, Random Forest, CatBoost, Extra-Trees, GPR, PLS, SVR, Elastic Net, and Linear Regression (LR). These methods are often used in traditional virtual metrology applications due to their short training times and relatively stable prediction performance.

Self-supervised learning methods included TabNet, VIME, SAINT, and SCARF. They enhance the generalization ability of the model's feature representations by generating pseudo-labels on unlabeled data to create pre-training tasks.

TABLE 2

| | CVD-3 | | CVD-4 | |
|---|---|---|---|---|
| Methods | RMSE | R² | RMSE | R² |
| Node | 21.914 ± 2.135 | 0.566 ± 0.048 | 26.465 ± 2.028 | 0.474 ± 0.037 |
| MDN | 22.270 ± 1.299 | 0.552 ± 0.030 | 26.244 ± 1.113 | 0.480 ± 0.049 |
| AutoInt | 20.577 ± 1.185 | 0.618 ± 0.015 | 26.649 ± 1.449 | 0.465 ± 0.036 |
| GANDALF | 21.712 ± 1.973 | 0.574 ± 0.050 | 27.280 ± 1.896 | 0.441 ± 0.033 |
| Mlp | 22.435 ± 2.399 | 0.546 ± 0.053 | 26.827 ± 2.639 | 0.459 ± 0.065 |
| Resnet | 23.874 ± 1.874 | 0.484 ± 0.060 | 27.762 ± 2.200 | 0.422 ± 0.036 |
| TabDPT | 21.251 ± 1.842 | 0.592 ± 0.038 | 22.995 ± 1.592 | 0.603 ± 0.016 |
| STG | 23.095 ± 1.446 | 0.515 ± 0.071 | 27.880 ± 2.755 | 0.417 ± 0.052 |
| FastAI | 24.989 ± 2.120 | 0.434 ± 0.076 | 28.852 ± 3.669 | 0.375 ± 0.095 |
| Tabtransformer | 22.488 ± 1.856 | 0.540 ± 0.073 | 27.499 ± 1.924 | 0.432 ± 0.031 |
| LGBM | 21.688 ± 2.103 | 0.575 ± 0.054 | 22.082 ± 1.503 | 0.634 ± 0.020 |
| XGB | 21.410 ± 2.033 | 0.586 ± 0.040 | 21.858 ± 0.995 | 0.640 ± 0.021 |
| RF | 21.670 ± 1.563 | 0.576 ± 0.017 | 23.193 ± 1.239 | 0.596 ± 0.020 |
| CAT | 21.422 ± 1.563 | 0.586 ± 0.025 | 22.380 ± 1.369 | 0.623 ± 0.029 |
| ET | 21.209 ± 2.364 | 0.594 ± 0.048 | 22.883 ± 1.436 | 0.606 ± 0.023 |
| GPR | 21.039 ± 2.472 | 0.601 ± 0.049 | 22.969 ± 1.581 | 0.602 ± 0.041 |
| PLS | 20.727 ± 2.208 | 0.613 ± 0.040 | 24.280 ± 1.578 | 0.555 ± 0.053 |
| SVR | 23.193 ± 1.416 | 0.512 ± 0.059 | 27.736 ± 2.823 | 0.423 ± 0.054 |
| EN | 20.535 ± 2.445 | 0.620 ± 0.051 | 24.497 ± 1.457 | 0.548 ± 0.035 |
| LR | 21.296 ± 1.721 | 0.591 ± 0.025 | 24.379 ± 1.323 | 0.548 ± 0.077 |
| Tabnet | 23.651 ± 1.611 | 0.493 ± 0.055 | 29.430 ± 2.845 | 0.345 ± 0.112 |
| VIME | 26.468 ± 2.036 | 0.368 ± 0.046 | 30.407 ± 1.907 | 0.306 ± 0.030 |
| SGT_SRL | 19.710 ± 1.310 | 0.649 ± 0.010 | 21.730 ± 1.590 | 0.640 ± 0.075 |

Data Collection and Preprocessing: Data from 12-inch wafer production was collected, containing 81 feature variables including reactive gas flow rates, RF power, temperature, and reaction chamber pressure. The data underwent missing value processing and normalization. Based on different processing tools, the data was divided into four datasets: CVD-1, CVD-2, CVD-3, and CVD-4. Each dataset was split into training, validation, and test sets, which were fed into the comparative models for evaluation. The experimental results are shown in Table 1 and Table 2.

As can be seen from comparing Table 1 and Table 2, SGT_SRL achieved RMSE values of 18.796, 26.908, 19.710, and 21.730, and R² values of 0.769, 0.590, 0.649, and 0.640 on the four different datasets, respectively. Except for its slightly inferior performance on the CVD-2 dataset, SGT_SRL outperformed all comparative methods in all other instances.

Ablation studies were conducted on the present invention, and the results are shown in Table 3 and Table 4.

TABLE 3

| | CVD-1 | | CVD-2 | |
|---|---|---|---|---|
| Methods | RMSE | R² | RMSE | R² |
| FTT_SG(SL, RL) | 18.796 ± 0.658 | 0.769 ± 0.021 | 26.908 ± 0.786 | 0.590 ± 0.058 |
| FTT_SG(RL) | 19.260 ± 0.911 | 0.758 ± 0.021 | 26.793 ± 1.053 | 0.596 ± 0.033 |
| FTT(RL) | 19.467 ± 0.731 | 0.752 ± 0.019 | 27.435 ± 1.316 | 0.576 ± 0.049 |
| FTT_SG | 19.552 ± 0.669 | 0.751 ± 0.011 | 27.372 ± 0.525 | 0.578 ± 0.041 |
| FTT(SL) | 19.525 ± 0.984 | 0.751 ± 0.016 | 27.331 ± 1.384 | 0.580 ± 0.030 |
| FTT | 19.835 ± 0.542 | 0.743 ± 0.009 | 27.544 ± 0.633 | 0.573 ± 0.036 |

TABLE 4

| | CVD-3 | | CVD-4 | |
|---|---|---|---|---|
| Methods | RMSE | R² | RMSE | R² |
| FTT_SG(SL, RL) | 19.710 ± 1.310 | 0.649 ± 0.010 | 21.730 ± 1.590 | 0.640 ± 0.075 |
| FTT_SG(RL) | 19.727 ± 1.632 | 0.649 ± 0.020 | 21.858 ± 1.500 | 0.639 ± 0.045 |
| FTT(RL) | 19.976 ± 1.714 | 0.640 ± 0.033 | 22.234 ± 1.868 | 0.627 ± 0.054 |
| FTT_SG | 19.858 ± 2.089 | 0.644 ± 0.041 | 22.360 ± 1.814 | 0.623 ± 0.050 |
| FTT(SL) | 20.039 ± 1.413 | 0.637 ± 0.029 | 22.819 ± 1.245 | 0.606 ± 0.056 |
| FTT | 20.194 ± 1.474 | 0.631 ± 0.033 | 22.683 ± 1.253 | 0.611 ± 0.050 |

From Table 3 and Table 4, it can be found that the complete model employing SL+RL+feature selection (FTT_SG(SL, RL)) performed best across all datasets. Among these, representation learning (RL) is the key factor enhancing model performance, while self-supervised learning (SL) contributed significantly on some datasets. Feature selection can improve model performance, but its effect is maximized only when combined with RL and SL.

The present invention also provides a self-supervised and representation learning-based thin film thickness prediction system for implementing the aforementioned embodiments. Terms such as “module” and “unit” used herein may refer to combinations of software and/or hardware capable of achieving predetermined functions. Although the system described in the following embodiments is preferably implemented in software, implementation via hardware, or a combination of software and hardware, is also possible.

The self-supervised and representation learning-based thin film thickness prediction system provided in this embodiment includes:
A training data preprocessing module, configured to collect raw wafer manufacturing process data and thin film thickness measurement data, preprocess successfully matched pairs of raw process data and measurement data to form a first training set, and preprocess unmatched raw process data to form a second training set;
A pre-training module, configured to pre-train an encoder using the second training set;
A fine-tuning module, configured to fine-tune the encoder obtained from the pre-training module using the first training set and simultaneously train a dynamic feature selector and a regression head;
A global prototype projection space initialization module, configured to use the dynamic feature selector to reduce the dimensionality of the process data in the first training set, and use the fine-tuned encoder on the dimensionality-reduced process data to initialize a global prototype projection space;
A representation learning module, configured to use the most recently updated encoder to generate embedded representations of the dimensionality-reduced process data, calculate the projection coordinates of the embedded representations in the global prototype projection space through a feature representation head, calculate a projection loss based on an optimal transport mechanism for the projection distribution, calculate a regression loss based on the regression head, simultaneously introduce a diversity loss and a global prototype orthogonality loss, and jointly use the total loss to iteratively update the encoder, regression head, feature representation head, and synchronously update the global prototype projection space;
A thin film thickness prediction module, configured to use actual wafer manufacturing process data as input, and predict the thin film thickness utilizing the dynamic feature selector, encoder, and regression head.

Regarding the system embodiment, since it basically corresponds to the method embodiment, relevant parts can be referred to the descriptions in the method embodiment, and the implementation methods of other modules will not be repeated here. The system embodiments described above are merely illustrative. Units described as separate components may or may not be physically separated, and components displayed as units may or may not be physical units, meaning they may be located in one place or distributed across multiple network units. Some or all of the modules may be selected according to actual needs to achieve the objectives of the solutions of the present invention. Those of ordinary skill in the art can understand and implement them without creative effort.

Embodiments of the system of the present invention can be applied to any device with data processing capability, which can be a device or apparatus such as a computer. The system embodiments may be implemented in software, hardware, or a combination of both. Taking software implementation as an example, as a logical entity, it is formed by the processor of any device with data processing capability reading the corresponding computer program instructions from a non-volatile memory into a memory and running them.

The embodiments described above only express several implementation modes of the present invention. Their descriptions are specific and detailed, but should not be construed as limiting the scope of the invention. For those of ordinary skill in the art, without departing from the concept of the present invention, various modifications and improvements can be made, all of which fall within the protection scope of the present invention.

What is claimed is:

1. A self-supervised and representation learning-based thin film thickness prediction method, characterized by comprising the following steps:
(1) Collecting raw wafer manufacturing process data and thin film thickness measurement data, preprocessing successfully matched pairs of raw process data and measurement data to form a first training set, and preprocessing unmatched raw process data to form a second training set;
(2) Pre-training an encoder using the second training set, then fine-tuning the encoder using the first training set while simultaneously training a dynamic feature selector and a regression head;
(3) Using the dynamic feature selector to reduce the dimensionality of the process data in the first training set, and using the fine-tuned encoder on the dimensionality-reduced process data to initialize a global prototype projection space;
(4) Using the most recently updated encoder to generate embedded representations of the dimensionality-reduced process data, calculating the projection coordinates of the embedded representations in the global prototype projection space through a feature representation head, calculating a projection loss based on an optimal transport mechanism for the projection distribution, calculating a regression loss based on the regression head, simultaneously introducing a diversity loss and a global prototype orthogonality loss, and jointly using the total loss to iteratively update the encoder, regression head, feature representation head, and synchronously update the global prototype projection space;
(5) Using actual wafer manufacturing process data as input, and predicting the thin film thickness utilizing the dynamic feature selector, encoder, and regression head.

2. The self-supervised and representation learning-based thin film thickness prediction method according to claim 1, characterized in that said preprocessing refers to preliminary screening of features in the process data, wherein the screened features include deposition time, buffer pressure, wafer processing temperature, lateral and top silane gas reaction times, and top, bias, and lateral radio frequency (RF) reflected power.

3. The self-supervised and representation learning-based thin film thickness prediction method according to claim 1, characterized in that when pre-training the encoder using the second training set, the K-Means clustering method is used to generate pseudo measurement data for the second training set as pseudo-labels for training, while simultaneously perturbing the process data in the second training set;
The optimization objective for generating pseudo-labels is:
$${min}_{C ∈ {R}^{w \times {K}_{s}}} \frac{1}{{N}_{u}} {\sum }_{i = 1}^{{N}_{u}} {min}_{{\tilde{y}}_{u , i} ∈ {\{ 0 , 1 \}}^{{K}_{s}}} {‖ sq ( {x}_{u , i} ⊙ m ) - C {\tilde{y}}_{u , i} ‖}_{2}^{2} ;$$
where, x_{u,i} represents the i-th unmatched raw process data, m represents a binary mask matrix used for preprocessing the raw process data, sq(.) represents the features of the preprocessed process data, with feature dimension w; C represents the cluster center matrix, \tilde{y}_{u,i} represents the pseudo-label of the i-th process data in the second training set, which is a one-hot encoding of dimension ks and
$${\tilde{y}}_{u , i}^{⊤} {1}_{{K}_{s}} = 1 ,$$
1_{K}_{ₛ} is an all-ones vector, Nᵤ represents the number of samples in the second training set,
$${‖ \cdot ‖}_{2}^{2}$$
represents the square of the L2 norm.

4. The self-supervised and representation learning-based thin film thickness prediction method according to claim 1, characterized in that said fine-tuning the encoder using the first training set while simultaneously training a dynamic feature selector and a regression head comprises:
Using the dynamic feature selector to screen features of the process data in the first training set, obtaining dimensionality-reduced process data;
Using the pre-trained feature encoder to generate embedded representations of the dimensionality-reduced process data;
Using the regression head to predict the thin film thickness based on the embedded representations;
Calculating a loss based on the predicted film thickness and the actual measurement data, and updating the parameters of the encoder, dynamic feature selector, and regression head.

5. The self-supervised and representation learning-based thin film thickness prediction method according to claim 4, characterized in that said dynamic feature selector is specifically:
Introducing a random gating variable z∈[0,1]^{d}, where the gating value zⱼ is defined as:
zⱼ=max(0,min(1,μⱼ+ϵⱼ));
where, μⱼ is the j-th trainable parameter in the dynamic feature selector, j=1,2, . . . d; d represents the number of features of a sample in the training set; ϵⱼ is an independent sampling parameter for the j-th trainable parameter, which follows a Gaussian distribution; feature screening is achieved by calculating the Hadamard product of the process data and the random gating variable z, and a regularization term is introduced during the training process of the dynamic feature selector.

6. The self-supervised and representation learning-based thin film thickness prediction method according to claim 1, characterized in that the initialization process of the global prototype projection space is:
Using the fine-tuned encoder to generate embedded representations of the dimensionality-reduced process data;
Clustering the embedded representations, considering each cluster center as a prototype, obtaining a global prototype projection space containing several prototypes.

7. The self-supervised and representation learning-based thin film thickness prediction method according to claim 6, characterized in that said calculating the projection coordinates of the embedded representation in the global prototype projection space through the feature representation head is expressed as:
rᵢ=fᵣ(Eᵢ);
The projection coordinate rᵢ of the embedded representation Eᵢ and the global prototype projection space satisfy the following relationship:
$${E}_{i} = {\sum }_{k = 1}^{{K}_{r}} {( {r}_{i} )}^{k} {β}_{k} ;$$
where, Kᵣ represents the number of prototypes in the global prototype projection space, βₖ represents the k-th prototype in the global prototype projection space, fᵣ(.) represents the feature representation head.

8. The self-supervised and representation learning-based thin film thickness prediction method according to claim 1, characterized in that said diversity loss calculation process is:
Dividing the range of measurement data in the first training set into several sub-intervals, considering process data within the same sub-interval as a positive sample pair, considering process data from different sub-intervals as a negative sample pair, and calculating a contrastive learning loss for the projection coordinates based on the positive and negative samples.

9. The self-supervised and representation learning-based thin film thickness prediction method according to claim 1, characterized in that said projection loss refers to the optimal transport distance loss between the distribution of projection coordinates and the distribution of embedded representations, and said global prototype orthogonality loss refers to the orthogonality constraint satisfied by the global prototype projection space.

10. A self-supervised and representation learning-based thin film thickness prediction system, used to implement the self-supervised and representation learning-based thin film thickness prediction method according to claim 1, characterized in that said system comprises:
A training data preprocessing module, configured to collect raw wafer manufacturing process data and thin film thickness measurement data, preprocess successfully matched pairs of raw process data and measurement data to form a first training set, and preprocess unmatched raw process data to form a second training set;
A pre-training module, configured to pre-train an encoder using the second training set;
A fine-tuning module, configured to fine-tune the encoder obtained from the pre-training module using the first training set and simultaneously train a dynamic feature selector and a regression head;
A global prototype projection space initialization module, configured to use the dynamic feature selector to reduce the dimensionality of the process data in the first training set, and use the fine-tuned encoder on the dimensionality-reduced process data to initialize a global prototype projection space;
A representation learning module, configured to use the most recently updated encoder to generate embedded representations of the dimensionality-reduced process data, calculate the projection coordinates of the embedded representations in the global prototype projection space through a feature representation head, calculate a projection loss based on an optimal transport mechanism for the projection distribution, calculate a regression loss based on the regression head, simultaneously introduce a diversity loss and a global prototype orthogonality loss, and jointly use the total loss to iteratively update the encoder, regression head, feature representation head, and synchronously update the global prototype projection space.
